(19) United States
(12) Patent Application Publication
(10) Pub. No.: US 2025/0275210 A1
(43) Pub. Date: Aug. 28, 2025

(54) Transistor Design Reducing Use of Gold

(71) Applicant: MACOM Technology Solutions Holdings, Inc., Lowell, MA (US)

(72) Inventors: Kyle Bothe, Cary, NC (US); Elizabeth Keenan, Cary, NC (US)

(21) Appl. No.: 18/585,387

(22) Filed: Feb. 23, 2024

(51) Int. Cl. H01L 29/40; H01L 23/48; H01L 29/20; H01L 29/66; H01L 29/778

(52) U.S. Cl. CPC H10D 64/111; H01L 23/481; H10D 30/015; H10D 30/475; H10D 62/8503

(57) ABSTRACT

Cost reduction of semiconductor transistors is achieved by reduction in the amount of expensive metal, such as gold, used to form metal contacts and conductive paths in integrated circuits. A semiconductor transistor structure is formed, and ohmic source and drain terminals formed thereon. A gate terminal is formed over an insulating layer in the active area between the source and drain terminals. A field plate is formed at least partially over the gate terminal. Interface layers are deposited over the source and drain terminals, using the field plate metal structure, such as in the same processing step as field plate deposition. Metal contacts are then deposited over the interface layers. The metal contacts are considerably thinner than required in the prior art to support high current densities. Because gold is often used in the metal contacts, their smaller size reduces costs by requiring less gold to achieve the same performance.

### BACKGROUND

Electrical circuits requiring high power handling capability while operating at high frequencies, such as R-band (0.5-1 GHZ), S-band (3 GHZ), X-band (10 GHZ), Ku-band (12-18 GHZ), K-band (18-27 GHZ), Ka-band (27-40 GHZ) and V-band (40-75 GHz) have become more prevalent. In particular, there is now a high demand for radio frequency (RF) transistor amplifiers that are used to amplify RF signals at frequencies of, for example, 500 MHz and higher (including microwave frequencies). These RF transistor amplifiers may need to exhibit high reliability, good linearity and handle high output power levels.

RF amplifiers are widely used in wireless communications systems and other applications. RF amplifiers are typically formed as semiconductor integrated circuit chips. Most RF amplifiers are implemented in silicon or using wide bandgap semiconductor materials, such as silicon carbide (SiC) and Group III nitride materials. As used herein, the term “Group III nitride” refers to those semiconducting compounds formed between nitrogen and the elements in Group III of the periodic table, usually aluminum (Al), gallium (Ga), and/or indium (In). The term also refers to ternary and quaternary compounds, such as GaN-based compounds AlGaN and AlInGaN. These compounds have empirical formulas in which one mole of nitrogen is combined with a total of one mole of the Group III elements.

Silicon-based RF amplifiers are typically implemented using laterally diffused metal oxide semiconductor (LDMOS) transistors. Silicon LDMOS RF amplifiers can exhibit high levels of linearity and may be relatively inexpensive to fabricate. Group III nitride-based RF amplifiers are typically implemented using High Electron Mobility Transistors (HEMT) and are primarily used in applications requiring high power and/or high frequency operation where LDMOS transistor amplifiers may have inherent performance limitations.

RF amplifiers may include one or more amplification stages, with each stage typically implemented as a transistor amplifier. In order to increase the output power and current handling capabilities, RF amplifiers are typically implemented in a “unit cell” configuration in which a large number of individual unit cell transistors are arranged electrically in parallel. The RF amplifier may be implemented as a single integrated circuit chip or “die,” or may include a plurality of dies. When multiple RF amplifier die are used, they may be connected in series and/or in parallel.

As noted above, Group III nitride-based RF amplifiers are often used in high power and/or high frequency applications. Typically, high levels of heat are generated within the Group III nitride-based RF amplifier die(s) during operation. If the RF die(s) become too hot, the performance (e.g., output power, efficiency, linearity, gain, etc.) of the RF amplifier may deteriorate and/or the RF amplifier die(s) may be damaged. As such, Group III nitride-based RF amplifiers are typically mounted in packages that may be optimized for heat removal.

Another consequence of high power RF amplifier is the generation of significant current densities in conductors formed on the transistors, such as metal contacts deposited over the transistor terminals (e.g., source and/or drain terminals), and metal interconnect layers. To conduct this current, metals with very high conductivity, such as gold and alloys of gold, are used, which are expensive. Additionally, the metal contacts and traces are deposited with a sufficient thickness to handle the current density (and concomitant thermal activity), adding to the cost. Many Communications Infrastructure (CIFR) applications are consumer devices, which are cost-sensitive, and would benefit from lower cost RF amplifiers. Additionally, advances in wireless communications technology, such as higher operating frequencies and beamforming, require antenna arrays having a very large number of antenna elements (e.g., thousands). Each antenna element (or small subset of antenna elements) is ideally driven by a separate power amplifier. Hence the sheer number of amplifiers makes communication equipment expensive. One way to reduce the cost of transistor amplifiers is to minimize the amount of expensive metal, such as gold, used in the semiconductor fabrication process.

The Background section of this document is provided to place embodiments of the present invention in technological and operational context, to assist those of skill in the art in understanding their scope and utility. Unless explicitly identified as such, no statement herein is admitted to be prior art merely by its inclusion in the Background section

### BRIEF SUMMARY

The following presents a simplified summary of the disclosure in order to provide a basic understanding to those of skill in the art. This summary is not an extensive overview of the disclosure and is not intended to identify key/critical elements of embodiments of the invention or to delineate the scope of the invention. The sole purpose of this summary is to present some concepts disclosed herein in a simplified form as a prelude to the more detailed description that is presented later.

According to aspects of the present disclosure described and claimed herein, cost reduction of semiconductor transistors is achieved by reduction in the amount of expensive metal, such as gold, used to form conductive paths in integrated circuits. A semiconductor transistor structure is formed on the upper surface of a substrate, and a metal layer is formed on the lower surface of the substrate, which may be grounded. Transistor terminals (i.e., source and drain) are formed on the semiconductor transistor structure using an ohmic metal structure. A field plate metal structure used in the formation of field plates, having a greater conductivity than the ohmic metal, and deposited in a relatively thin layer, is deposited over most, but not all, of the surface of the ohmic metal terminals, in layers referred to herein as interface layers. Metal contacts, which may be formed from the same or similar material as the interface layers, are deposited in a thicker layer over most, but not all, of surface of the interface layers. In one aspect, the source terminal extends over a substrate via connecting the source terminal to the metal layer on the lower surface of the substrate. In one aspect, a gate terminal is formed and protected, and a field plate is formed over at least part of the gate terminal in the same fabrication step as the interface layers are formed. The interface layers and metal contacts together support the current densities required for high power and/or high frequency operation; however, the metal contacts are thinner than those required in the prior art, allowing for cost savings, particularly as gold is one metal often used.

One aspect relates to a semiconductor transistor. The transistor includes a substrate having upper and lower surfaces, and a semiconductor transistor structure formed on the upper surface of the substrate. The transistor also includes source and drain terminals formed directly on the semiconductor structure. The source and drain terminals comprise an ohmic metal structure having a first conductivity. The transistor further includes an interface layer formed directly on each of the source and drain terminals. The interface layers comprise a field plate metal structure having a second conductivity greater than the first conductivity, and the interface layers have a first thickness. The transistor additionally includes a metal contact formed directly on each interface layer. metal contacts comprise a metal construction having a third conductivity greater than the first conductivity, and a second thickness greater than the first thickness.

Another aspect relates to a method of manufacturing a semiconductor transistor. A substrate having upper and lower surfaces is provided. A semiconductor transistor structure is formed on the upper surface of the substrate. Source and drain terminals are formed directly on the semiconductor transistor structure. The source and drain terminals comprise an ohmic metal structure having a first conductivity. An interface layer is formed directly on each of the source and drain terminals. The interface layers comprise a field plate metal structure having a second conductivity greater than the first conductivity. The interface layers have a first thickness. A metal contact is formed directly on each interface layer. The metal contacts comprise a metal construction having a third conductivity greater than the first conductivity. The metal contacts have a second thickness greater than the first thickness.

### BRIEF DESCRIPTION OF THE DRAWINGS

FIG. 1 is a schematic cross-sectional view of a conventional HEMT device.

FIG. 2 is a schematic cross-sectional view of a HEMT device according to aspects of the present disclosure.

FIG. 3 is a schematic top view of the HEMT device of FIG. 2.

FIG. 4 is a flow diagram of a method of manufacturing a semiconductor transistor.

FIG. 5 is a cross-sectional view of the HEMT of FIG. 2 in a first packaging option.

FIG. 6 is a cross-sectional view of the HEMT of FIG. 2 in a second packaging option.

FIG. 7 is a cross-sectional view of the HEMT of FIG. 2 in a third packaging option.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Reference now will be made in detail to aspects of the present disclosure, one or more examples of which are illustrated in the drawings. Each example is provided by way of explanation of the aspect, not limitation of the present disclosure. In fact, it will be apparent to those skilled in the art that various modifications and variations can be made to the aspects without departing from the scope or spirit of the present disclosure. For instance, features illustrated or described as part of one aspect can be used with another aspect to yield a still further aspect. Thus, it is intended that aspects of the present disclosure cover such modifications and variations.

Transistor devices, such as High Electron Mobility Transistors (HEMT), may be used in power electronics applications. HEMTs fabricated in Group III nitride-based material systems may have the potential to generate large amounts of radio frequency (RF) power because of the combination of material characteristics that includes high breakdown fields, wide bandgaps, large conduction band offset, and/or high saturated electron drift velocity. As such, Group III nitride based HEMTs may be promising candidates for high frequency and/or high-power RF applications, as well as for low frequency high power switching applications, both as discrete transistors and as coupled with other circuit elements, such as in Monolithic Microwave Integrated Circuit (MMIC) devices.

Transistor devices such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a 2-Dimensional Electron Gas (2DEG) is formed at the heterojunction of two semiconductor materials with different bandgap energies, where the smaller bandgap material has a higher electron affinity. The 2DEG is an accumulation layer in the smaller bandgap material and can include a very high sheet electron concentration. Additionally, electrons that originate in the wider-bandgap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

Aspects of the present disclosure are described herein with reference to plan view and cross-section illustrations that are schematic illustrations of idealized embodiments (and intermediate structures) of aspects of the disclosure. The thickness of layers and regions in the drawings may be exaggerated for clarity. Additionally, variations from the shapes of the illustrations as a result, for example, of manufacturing techniques and/or tolerances, are to be expected. Thus, aspects of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some aspects of the disclosure are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other transistor devices without deviating from the scope of the present disclosure. For instance, aspects of the present disclosure may be implemented in any transistor having a field plate or other transistors devices with metal structures, such as silicon carbide-based MOSFETs.

In the drawings and specification, there have been disclosed typical embodiments and, although specific terms are employed, they are used in a generic and descriptive sense only and not for purposes of limitation of the scope set forth in the following claims.

With reference now to the Figures, example aspects of the present disclosure will now be set forth. These aspects are described herein with reference to a Gallium Nitride (GaN) High Electron Mobility Transistor (HEMT), but are not limited to such implementation. To provide a full and complete disclosure enabling one of skill in the art to make and use the present disclosure, a description of a GaN HEMT is first presented. The discussion will then shift to the metal layers overlying a semiconductor transistor structure (again, using GaN HEMT as merely an example), which provide conductivity for interconnection with other circuitry.

FIG. 1 depicts a cross-sectional view of a conventional HEMT device 10. FIG. 1 is intended to represent structures for identification and description and is not intended to represent the structures to physical scale. The HEMT device 10 includes a semiconductor transistor structure 12. The semiconductor transistor structure 12, in this representative example, is a Group III-nitride HEMT structure.

As used herein, the term “Group Ill nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements.

The semiconductor transistor structure 12 is formed on a substrate 14. The substrate 14 may be a semiconductor material. For instance, the substrate 14 may be a silicon substrate, a silicon carbide (SiC) substrate, a sapphire substrate, or other suitable substrate. In some aspects, the substrate 14 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some aspects of the present disclosure, the SiC bulk crystal of the substrate 14 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547; 5,200,022; and 6,218,680; the disclosures of which are incorporated by reference herein in their entireties. Although SiC may be used as a substrate material, aspects of the present disclosure may utilize any suitable substrate, such as sapphire (Al2O3), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 14 may be a SiC wafer, and the HEMT device 10 may be formed, at least in part, via wafer-level processing, and the wafer may then be diced to provide a plurality of individual HEMT devices 10 that may include one or more transistor cells.

In some aspects of the present disclosure, the substrate 14 of the HEMT device 10 may be a thinned substrate 14. In some embodiments, the thickness of the substrate 14 may be about 100 μm or less, such as about 75 μm or less, such as about 50 μm or less.

The semiconductor transistor structure 12 includes a channel layer 16 on an upper surface 14A of the substrate 14 (or on optional layers, not shown in FIG. 1, deposited over the substrate, such as an optional buffer or nucleation layer). The semiconductor transistor structure 12 also includes a barrier layer 18 on an upper surface of the channel layer 16. In some aspects, the channel layer 16 and the barrier layer 18 may each be formed by epitaxial growth. Techniques for epitaxial growth of Group III nitrides have been described in, for example, U.S. Pat. Nos. 5,210,051, 5,393,993, and 5,523,589, the disclosures of which are incorporated by reference herein in their entireties. The channel layer 16 has a bandgap that is less than the bandgap of the barrier layer 18. The channel layer 16 has a larger electron affinity than the barrier layer 18. The channel layer 16 and the barrier layer 18 include Group III nitride-based materials.

In some aspects, the channel layer 16 is a Group III nitride, such as AlₓGa₁₋ₓN, where x is about 0.1 or less, provided that the energy of the conduction band edge of the channel layer 16 is less than the energy of the conduction band edge of the barrier layer 18 at the interface between the channel layer 16 and barrier layer 18 (also known as a heterojunction). In some embodiments, the aluminum mole fraction x is approximately 0 (e.g., less than 5%, such as 0%), indicating that the channel layer 16 is GaN. The channel layer 16 may or may not include other Group III-nitrides such as InGaN, AlInGaN or the like. The channel layer 16 may be undoped (“unintentionally doped”). In some aspects, the channel layer 16 may be doped, for instance with iron (Fe). The channel layer 16 may be a multi-layer structure, such as a superlattice or combinations of GaN, AlGaN, or the like. The channel layer 16 may be under compressive strain in some aspects. In some aspects, the channel layer 16 can include an implanted region extending into the channel layer 16. The implanted region may have implanted dopants to provide, for instance, N-type doping of the semiconductor structure in the implanted region, such as in the region on which source and drain terminals are formed.

The barrier layer 18 includes a Group III nitride-based layer having a surface 18A positioned on a surface 16A of the channel layer 16. The barrier layer 18 is a Group III-nitride, such as Al_{y}Ga_{1-y}N, where y is the aluminum mole fraction in the barrier layer 18. In some embodiments, the aluminum mole fraction y is such that y is in a range of about 0.25 to about 0.40 (e.g., the aluminum mole fraction is in a range of about 25% to about 40%), indicating that the barrier layer is an AlGaN layer. For instance, in some embodiments, the aluminum mole fraction y is such that y is in a range from about 0.25 to about 0.35, such as about 0.25 to 0.30, such as about 0.30 (e.g., the aluminum mole fraction is in a range of about 25% to about 35%, such as about 25% to about 30%, such as about 30%). Additionally or alternatively, in some aspects, the aluminum mole fraction y is such that y is in a range of about 0.30 to about 0.40, such as about 0.35 to about 0.40, such as about 0.35 (e.g., the aluminum mole fraction is in a range of 30% to 40%, such as in a range of about 35% to about 40%, such as about 35%). For instance, in some implementations, the barrier layer 18 can include a higher aluminum mole fraction to achieve low contact resistance for high frequency applications.

The energy of the conduction band edge of the barrier layer 18 is greater than the energy of the conduction band edge of the channel layer 16 at the interface between the channel layer 16 and barrier layer 18. The barrier layer 18 may include other Group III elements (e.g., In) without deviating from the scope of the present disclosure. The barrier layer 18, in some examples, may be a multilayer structure. The multilayer structure may include multiple Group III nitride-based layers with differing aluminum mole fractions.

The barrier layer 18 may have a thickness less than about 130 Angstroms, such as in a range of about 10 Angstroms to about 130 Angstroms. For instance, in some aspects, the barrier layer can have a thickness in a range of about 70 Angstroms to about 100 Angstroms, such as about 80 Angstroms to about 90 Angstroms. For instance, in some implementations, the barrier layer 18 can have a reduced thickness to achieve low contact resistance for high frequency applications. The channel layer 16 and/or the barrier layer 18 may be deposited, for example, by metal-organic chemical vapor deposition (MOCVD), molecular beam epitaxy (MBE), or hydride vapor phase epitaxy (HVPE).

A 2DEG 20 is induced in the channel layer 106 at an interface between the channel layer 106 and the barrier layer 108. The 2DEG 20 is highly conductive and allows conduction between the source and drain regions of the HEMT device 10.

While the HEMT device 10 of FIG. 1 is shown with a substrate 14, channel layer 16 and barrier layer 18 for purposes of illustration, the HEMT device 10 may include additional layers/structures/elements. For instance, the HEMT device 10 may include a buffer layer(s)/nucleation layer(s)/transition layer(s) (not shown) between substrate 14 and the channel layer 16. For example, an AlN buffer layer may be on the upper surface 14A of the substrate 14 to provide an appropriate crystal structure transition between a SiC substrate 14 and the channel layer 16. The optional buffer/nucleation/transition layers may be deposited by MOCVD, MBE, and/or HYPE.

The HEMT device 10 may include a cap layer (not shown) on the barrier layer 18. HEMT structures including substrates, channel layers, barrier layers, and other layers are discussed by way of example in U.S. Pat. Nos. 5,192,987; 5,296,395; 6,316,793; 6,548,333; 7,544,963; 7,548,112; 7,592,211; 7,615,774; 7,709,269; 7,709,859; and 10,971,612, the disclosures of which are incorporated by reference herein in their entireties. Additionally, strain balancing transition layer(s) may also and/or alternatively be provided as described, for example, in U.S. Pat. No. 7,030,428, the disclosure of which is incorporated by reference herein.

The HEMT device 10 includes a source terminal 20 on the semiconductor transistor structure 12. The HEMT device 100 also includes a drain terminal 22 on the semiconductor transistor structure 12. The source terminal 20 and the drain terminal 22 are laterally spaced apart from each other. The source terminal 20 and the drain terminal 22 comprise an ohmic metal, which forms an ohmic contact to a Group III nitride-based semiconductor material. Suitable metals include refractory metals, such as titanium (Ti), tungsten (W), titanium tungsten (TiW), silicon (Si), titanium tungsten nitride (TiWN), tungsten silicide (WSi), rhenium (Re), niobium (Nb), nickel (Ni), gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some aspects, the source terminal 20 and/or the drain terminal 22 may include a plurality of layers to form an ohmic contact as described, for example, in U.S. Pat. Nos. 8,563,372 and 9,214,352, the disclosures of which are incorporated by reference herein in their entireties.

The HEMT device 10 includes a gate terminal 24 on the semiconductor transistor structure 12. The gate terminal 24 has a gate length LG. The gate length LG is the length of the gate contact 24 along the portion of the gate contact 24 that is on the semiconductor transistor structure 12 (e.g., the length of the lowermost portion of the gate terminal 24 in contact with the semiconductor transistor structure 12). In some aspects, the gate length LG may be about 200 nm or less, such as about 100 nm or less, such as in a range of about 60 nm to about 100 nm, such as in a range of about 70 nm to about 90 nm. A distance Lgd between the gate terminal 24 and the drain terminal 22 may be, for instance, in a range of 1.8 μm to about 2.2 μm, such as about 1.98 μm. A distance Lgs between the gate terminal 24 and the source terminal 20 may be, for instance, in a range of about 0.4 μm to about 0.8 μm, such as about 0.6 μm.

The material of the gate terminal 24 may be chosen based on the composition of the barrier layer 18, and may, in some aspects, be a Schottky contact. Materials capable of making a Schottky contact to a Group III nitride-based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

In some aspects of the present disclosure, such as that depicted in FIG. 1, the gate terminal 24 is a T-shaped gate and/or a gamma gate, the formation of which is discussed by way of example in U.S. Pat. Nos. 8,049,252; 7,045,404; and 8,120,064, the disclosures of which are incorporated by reference herein in their entireties. The gate terminal 24 may have an overhang toward the drain terminal 22. The length ┌_{D} of the overhang toward the drain terminal 22 may be in a range of about 0.15 μm to about 0.25 μm, such as about 0.2 μm. The gate terminal 24 may have an overhang toward the source terminal 20. The length ┌_{S} of the overhang toward the source terminal 20 may be in a range of about 0.15 μm to about 0.25 μm, such as about 0.2 μm.

The source terminal 20 is coupled, via a first metal layer contact 26 connecting to the source terminal 20, to a via 28 that extends from a lower surface 14B of the substrate 14, through the substrate 14 and semiconductor transistor structure 12 to the upper surface of the semiconductor transistor structure 12. The first metal layer contact 26 is formed from metal or other highly conductive material, including, for example, copper, cobalt, gold, and/or a composite metal. In some aspect, to achieve a high conductivity, the first metal layer contact 26 is formed from gold or an alloy of gold, which is expensive.

A back metal layer 30 is formed on the lower surface 14B of the substrate 14 and on side walls of the via 28. The back metal layer 30 is conductively coupled to the first metal layer contact 26. Thus, the back metal layer 30, and a signal coupled thereto, such as RF signal ground, is electrically connected to the source terminal 20 through the first metal layer contact 26. Although FIG. 1 is not to scale, it does show schematically that the first metal layer contact 26 is considerably thicker than the source or drain terminals 20, 22, or the semiconductor epitaxial layers 16, 18. This thickness is necessary due to the high current density that can result from operation of the HEMT device 10 at high power and/or high frequency. For example, the thickness of the first metal layer contact 26 may be in the range of 1-4 μm.

In some aspects, the via 28 has an oval or circular cross-section when viewed in a plan view. However, the present disclosure is not limited thereto. In some aspects, a cross-section of the via 28 may be a polygon or other shape, as will be understood by one of ordinary skill in the art using the disclosures provided herein. In some aspects, dimensions of the via 28 (e.g., a length and/or a width) may be such that a largest cross-sectional area of the via 28 is about 1000 μm² or less. The cross-sectional area may be taken in a direction that is parallel to the lower surface 14B of the substrate 14 (e.g., the X-Y plane of FIG. 1). In some aspects, the largest cross-sectional area of the via 28 may be that portion of the via 28 that is adjacent the lower surface 14B of the substrate 14 (e.g., the opening of the via 28). For example, in some aspects, a greatest width (e.g., in the X direction in FIG. 1) may be about 16 μm and a greatest length (e.g., in the Y direction in FIG. 1) may be about 40 μm, though the present disclosure is not limited thereto. In some aspects, sidewalls of the via 28 may be inclined and/or slanted with respect to the lower surface 14B of the substrate 14. In some aspects, the sidewalls of the via 28 may be approximately perpendicular to the lower surface 14B of the substrate 14.

The HEMT device 10 includes a dielectric structure 36 on the semiconductor transistor structure 12. The dielectric structure 36 includes a first dielectric layer 32 and a second dielectric layer 34. The first dielectric layer 32 directly contacts the upper surface of the semiconductor transistor structure 12. At least a portion of the first dielectric layer 32 is between the semiconductor transistor structure 12 and at least a portion of the gate terminal 24. For instance, at least a portion of the first dielectric layer 32 may be between the semiconductor transistor structure 12 and the overhang of the gate terminal 24. In some aspects, the thickness of the first dielectric layer 32 may be about 1450 Angstroms or less, such as in a range of about 800 Angstroms to about 1450 Angstroms, such as about 1200 Angstroms. In this way, the overhang of the T-shaped or Gamma-shaped gate terminal 24 is separated from the semiconductor transistor structure 12 by the thickness of the first dielectric layer 32. The first dielectric layer 32 may be a SiN layer. Other suitable dielectric materials may be used without deviating from the scope of the present disclosure. For instance, the first dielectric layer 32 may be SiO2, Si, Ge, MgOx, MgNx, ZnO, SiNx, SiOx, alloys or layer sequences thereof, or epitaxial materials.

The dielectric structure 36 may include a second dielectric layer 34 on the first dielectric layer 32. The second dielectric layer 34 may be the same dielectric material or a different dielectric material relative to the first dielectric layer 32. For instance, the second dielectric layer may be a SiN layer. Other suitable dielectric materials may be used without deviating from the scope of the present disclosure. For instance, the second dielectric layer 34 may be SiO2, Si, Ge, MgOx, MgNx, ZnO, SiNx, SiOx, alloys or layer sequences thereof, or epitaxial materials. In some embodiments, the thickness of the second dielectric layer 34 may be about 2800 Angstroms or less, such as in a range of about 1500 Angstroms to about 2800 Angstroms, such as about 2100 Angstroms.

In some embodiments, the thickness of the dielectric structure 36 may be about 3600 Angstroms or less, such as in a range of about 3000 Angstroms to about 3600 Angstroms, such as about 3300 Angstroms.

One or more field plates 38 may be formed on the dielectric structure 36, as illustrated in FIG. 1. At least a portion of the field plate 38 overlaps the gate terminal 24. At least a portion of the field plate 38 is formed on a portion of the second dielectric layer 34. In some aspects of the present disclosure, the field plate 38 is conductively coupled to the gate terminal 24. The field plate 38 may reduce the peak electric field in the HEMT device 10, which results in increased breakdown voltage and reduced charge trapping. The reduction of the electric field may also yield other benefits such as reduced leakage currents and enhanced reliability. Field plates and techniques for forming field plates are discussed, by way of example, in U.S. Pat. Nos. 7,550,783 and 8,120,064, the disclosures of which are incorporated by reference herein in their entireties.

First metal layer contacts 26 and 40 connect to the source and drain terminals 20, 22, respectively, through the dielectric structure 36 as illustrated in FIG. 1. The first metal layer contacts 26, 40 may include metal or other highly conductive material, including, for example, copper, cobalt, gold, and/or a composite metal. In particular, for high power and/or high frequency applications, to handle high current density, the first metal layer contacts 26, 40 have a thickness in the range 1-4 μm, and are typically formed using gold or alloys of gold.

A HEMT transistor cell may be formed by the active region between the source terminal 20 and the drain terminal 22 under the control of the gate terminal 24 between the source terminal 20 and the drain terminal 22. FIG. 1 depicts a cross-sectional view of one unit or cell of an HEMT device 10 for purposes of illustration. The HEMT device unit or cell 10 may be formed adjacent to additional HEMT device cells and may share, for instance, a source contact 20 with adjacent HEMT device cells. The HEMT device 10 may be formed, at least in part, via wafer-level processing, and the wafer may then be diced to provide a plurality of individual HEMT devices 10.

In some aspects of the present disclosure, the semiconductor transistor structure 12 may include implanted regions under the source terminal 20 and drain terminal 22 (not shown). The implanted regions include a distribution of implanted dopants extending into the channel layer 16. The implanted dopants may provide, for instance, for N-type doping of the semiconductor transistor structure 12. The implanted dopants may be, for instance, silicon or germanium dopants. The implanted region may have a distribution of implanted dopants that extends to a depth from a surface (e.g., a top surface) of the semiconductor transistor structure 12. The depth may be about 200 Angstroms or greater, such as about 250 Angstroms or greater, such as in a range of about 200 Angstroms to about 300 Angstroms. For instance, in some aspects of the present disclosure, the implanted region 302 can extend to a depth of about 200 Angstroms to about 300 Angstroms beneath a surface of the Group III-nitride semiconductor structure. In particular, the implanted region can extend completely through the barrier layer 18 and into the channel layer 16. The distribution of implanted dopants may extend through other layers, if present, such as a cap layer.

The implanted regions may have a peak dopant concentration. In some aspects of the present disclosure, a peak dopant concentration of the distribution of implanted dopants in the implanted regions is in the channel layer 16. For instance, the implanted regions may be doped such that the distribution of implanted dopants is greater at a portion of the implanted regions at a depth of the channel layer 16 than at a portion of the implanted regions at a depth of the barrier layer 18 (and/or another layer). In some examples, the distribution of implanted dopants may provide a substantially uniform concentration of implanted dopants throughout the implanted regions of the semiconductor transistor structure 12. In some aspects of the present disclosure, a peak dopant concentration of the distribution of implanted dopants can be about 1×10¹⁸ dopants/cm³.

The foregoing description fully enables one of skill in the art to make and use, e.g., an HEMT 10 (or other semiconductor transistor). Notably, as described above, first metal layer contacts 26, 40 have substantial thickness, and a second conductivity significantly greater than the first conductivity of the ohmic metal in source and drain terminals 20, 22. Typically, to achieve this second conductivity, the first metal layer contacts 26, 40 are formed from gold or an alloy of gold. This accounts for a significant portion of the cost of HEMTs 10 designed for high power and/or high frequency operation.

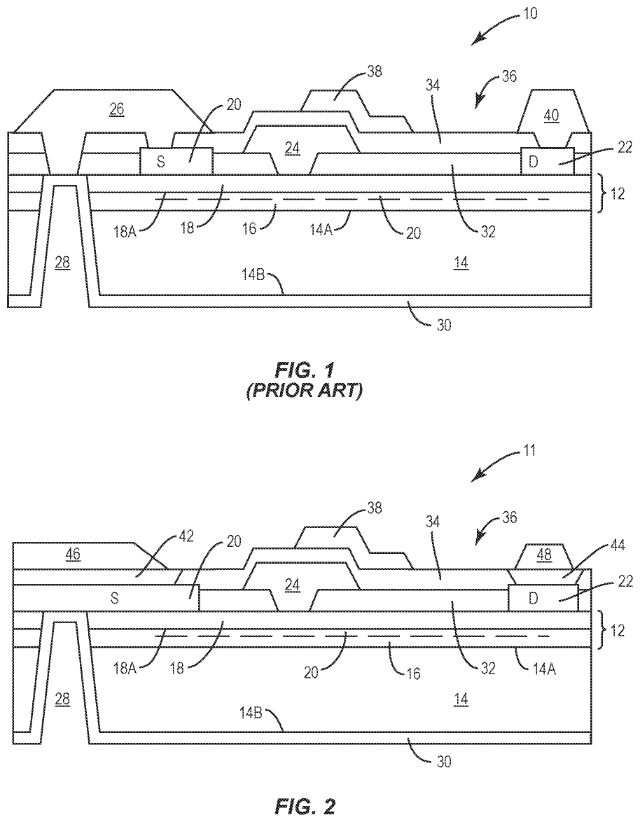

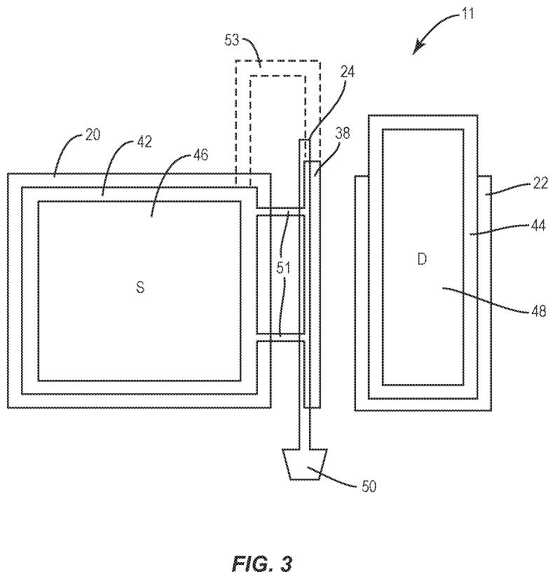

FIG. 2 shows an HEMT 11 (or other semiconductor transistor) according to aspects of the present disclosure, in cross section (not to scale). FIG. 3 shows a plan (top) view of the HEMT 11. As shown in FIG. 3, the source and drain terminals 20, 22 define an active area of the semiconductor transistor structure 12 between them, with a gate terminal 24 overlying the active area. A gate terminal bond pad 50 connects to the gate terminal 24, and provides for connectivity to other circuitry. The source and drain terminals 20, 22 may extend a length, in the longitudinal direction of the gate terminal 24, in the range of 15 μm to 750 μm. The field plate 38 lies partially over the gate terminal 24, and extends partially toward the drain terminal 22. In one aspect, as depicted in FIG. 3, the field plate 38 is connected to the source terminal 20 via two buses 51, which are routed over the active area of the semiconductor transistor structure 12. One of numerous possible alternative routes for such connection, which avoids the active area, is shown in dashed lines at 53.

The semiconductor transistor structure 12 of the HEMT 11 is as shown in FIG. 1 and described above, and will not be further elaborated. As with the HEMT 10 of FIG. 1, the HEMT 11 of FIGS. 2 and 3 includes source and drain terminals 20, 22 comprising an ohmic metal structure having a first conductivity. The ohmic metal structure may combine platinum (Pt), nickel (Ni), silicon (Si), and titanium (Ti), producing a nickel silicide. For example, the ohmic metal structure comprise a stack of Pt/Ni/Si/Ti (top to bottom). The source and drain terminals 20, 22 may be deposited directly on the semiconductor transistor structure 12, to a thickness in the range from 100 A to 3000 A, such as from 1000 A to 2000 A.

Different to the HEMT 10, however, in the HEMT 11, the source terminal 20 extends over, and electrically contacts, the via 28, which is electrically connected to a metal layer 30 on the lower side 14B of the substrate 14. This lower metal layer 30 may be connected to a signal or reference voltage, such as RF signal ground.

Also different to the HEMT 10, in the HEMT 11, an interface layer 42 is formed directly on most, but not all, of the surface of the source terminal 20. Additionally, an interface layer 44 is formed directly on most, but not all, of the surface of the drain terminal 22. The interface layers 42, 44 are preferably deposited at the same time that the field plate 38 is deposited partially over the gate terminal 24. The interface layers 42, 44 (and the field plate 38) comprise a field plate metal structure having a second conductivity greater than the first conductivity (of the ohmic metal structure forming the source and drain terminals 20, 22). In particular, the field plate metal structure may comprise gold (Au) or an alloy of gold, and other metals, such as Pt and Ti. For example, the field plate metal structure may comprise a stack of Ti/Au/Pt/Ti (top to bottom). The field plate metal layers 42, 44 may have a first thickness, such as in the range of 500 A to 9000 A.

As shown in both FIGS. 2 and 3, the interface layers 42, 44 are deposited directly on most, but not all, of the surfaces of the source and drain terminals 20, 22, respectively. In particular, the interface layers 42, 44 leave exposed an edge, or rim, around at least three sides, or all four sides, of the respective ohmic metal terminals 20, 22. As one example, there may be 0.05 μm to 3 μm of the source and drain terminals 20, 22 exposed around the interface layers 42, 44. This provides for film adhesion and reliability improvements, such as to prevent delamination.

A metal contact 46 is deposited directly on most, but not all, of the surface of the interface layer 42. A metal contact 48 is deposited directly on most, but not all, of the surface of the interface layer 44. The metal contacts 46, 48 may comprise a first metal structure, which may combine Ti, Pt, and Au. For example, the metal contacts 46, 48 may comprise a stack of Ti/Pt/Au/Pt/Au/Ti (top to bottom). The metal contacts 46, 48 have a third conductivity greater than the first conductivity (of the ohmic metal forming the source and drain terminals 20, 22). The third conductivity may be similar or equal to the second conductivity (of the field plate metal forming the interface layers 42, 44). The metal contacts 46, 48 may be deposited directly on the interface layers 42, 44, to a second thickness greater than the first thickness, such as in the range 0.4 μm to 6 μm, such as 2-4 μm. The metal contacts 46, 48 leave exposed an edge, or rim, around at least three sides, or all four sides, of the respective interface layers 42, 44. As one example, there may be 0.5 μm to 5 μm of interface layer 42, 44 exposed around the metal contacts 46, 48. This improves the current handling capability of the metal contacts 46, 48.

The combination of interface layers 42, 44 and metal contacts 46, 48 support the high current densities that in the prior art required much thicker metal contacts 26, 40 (FIG. 1). Accordingly, the HEMT 11 according to aspects of the present disclosure can achieve the same performance as prior art HEMTs 10, but with thinner metal contacts. In fact, aspects of the present disclosure reduce the amount of Au in the metal contacts by approximately 20%, without sacrificing high power or high frequency performance. This reduces the overall use of gold in an HEMT 11 by approximately 15%, allowing high performance transistor devices to be produced at significantly reduced cost.

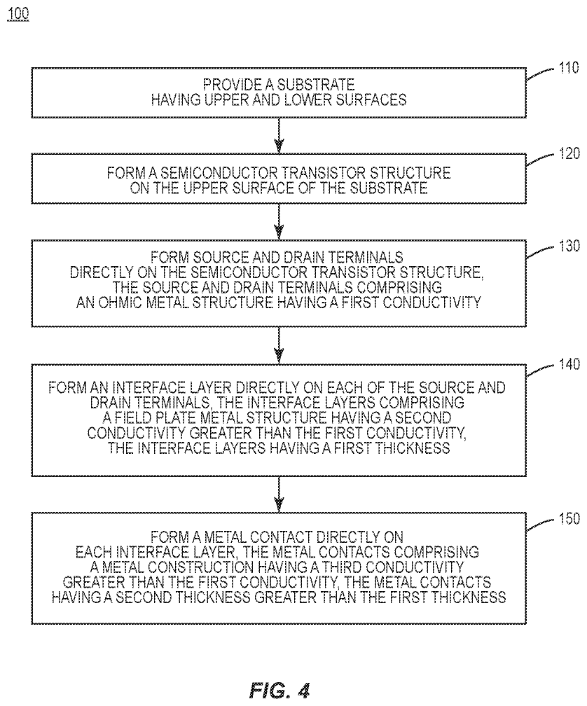

FIG. 4 depicts the steps in a method 100 of manufacturing a semiconductor transistor, such as the HEMT 11 depicted in FIGS. 2 and 3. A substrate having upper and lower surfaces is provided (block 110). A semiconductor transistor structure 12 is formed on the upper surface of the substrate (block 120). Source and drain terminals 20, 22 are formed directly on the semiconductor transistor structure 12 (block 130). The source and drain terminals 20, 22 comprise an ohmic metal structure having a first conductivity. An interface layer 42, 44 is formed directly on each of the source and drain terminals 20, 22 (block 140). The interface layers 42, 44 comprise a field plate metal structure having a second conductivity greater than the first conductivity. The interface layers 42, 44 have a first thickness. A metal contact 26, 40 is formed directly on each interface layer 42, 44 (block 150). The metal contacts 26, 40 comprise a metal structure having a third conductivity greater than the first conductivity. The metal contacts 26, 40 have a second thickness greater than the first thickness.

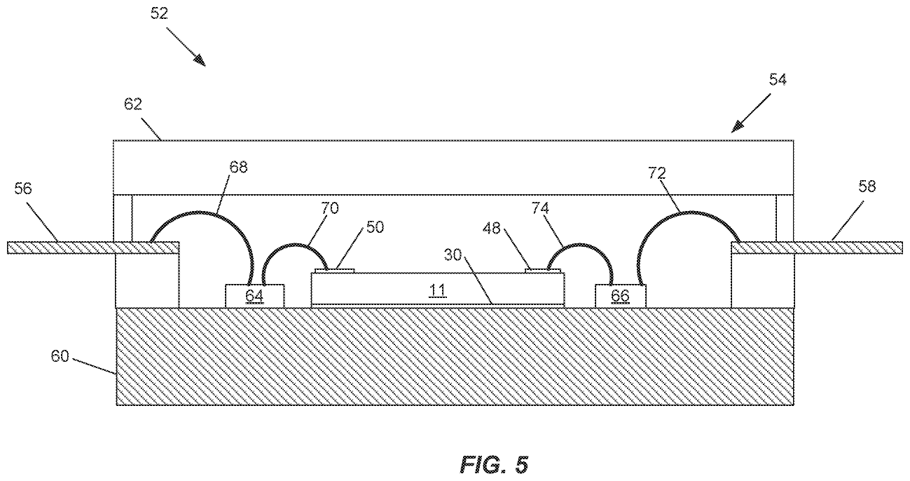

The HEMT 11 (or other transistor) may be packaged in a variety of ways. FIG. 5 shows a Group III nitride-based RF amplifier 52, which includes a unit cell configuration of parallel HEMTs 11 mounted within an open cavity package 54. The package 54 includes a gate lead 56, a drain lead 58, a metal flange 60 and a ceramic sidewall and lid 62. The HEMT 11 is mounted on the upper surface of the metal flange 60 in a cavity formed by the metal flange 60 and the ceramic sidewall and lid 62.

Input matching circuits 64 and/or output matching circuits 66 may also be mounted within the housing 62. The matching circuits 64, 66 may be impedance matching circuits that match the impedance of the fundamental component of RF signals input to or output from the RF transistor amplifier 52 to the impedance at the input or output of the HEMT 11, respectively. Alternatively or additionally, the matching circuits 64, 66 may be harmonic termination circuits that are configured to short to ground harmonics of the fundamental RF signal that may be present at the input or output of the HEMT 11, such as second order or third order harmonics. As schematically shown in FIG. 5, the input and output matching circuits 64, 66 may be mounted on the metal flange 60. The gate lead 56 may be connected to the input matching circuit 64 by one or more first bond wires 68, and the input matching circuit 64 may be connected to the gate terminal 50 of HEMT 11 by one or more second bond wires 70. Similarly, the drain lead 58 may be connected to the output matching circuit 66 by one or more fourth bond wires 72, and the output matching circuit 66 may be connected to the drain terminal metal contact 48 of HEMT 11 by one or more third bond wires 74. The source terminal 20 of the HEMT 11 may connect to the metal layer 30 on the lower side of the substrate 14, which may directly contact the metal flange 60. The metal flange 60 may provide the electrical connection to the source terminal 20 and may also serve as a heat dissipation structure. The first through fourth bond wires 68-74 may form part of the input and/or output matching circuits. The housing 62 may comprise a ceramic housing, and the gate lead 56 and the drain lead 58 may extend through the housing 52. The housing 52 may comprise multiple pieces, such as a frame that forms the lower portion of the sidewalls and supports the gate and drain leads 56, 58, and a lid that is placed on top of the frame. The interior of the device may comprise an air-filled cavity.

The metal flange 60 may act as a heat sink that dissipates heat that is generated in the HEMT 11. The heat is primarily generated in the upper portion of the HEMT 11 where relatively high current densities are generated in, for example, the channel regions of the unit cell transistors. This heat may be transferred though both the source vias 28 and the substrate 14 to the metal flange 60.

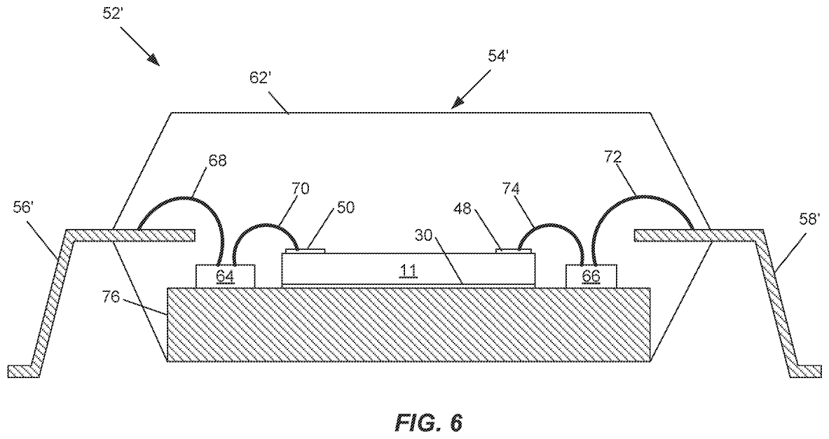

FIG. 6 is a schematic side view of a conventional packaged Group III nitride-based RF transistor amplifier 52′ that is similar to the RF transistor amplifier 52 discussed above with reference to FIG. 5. RF transistor amplifier 52′ differs from RF transistor amplifier 52 in that it includes a different package 54′. The package 54′ includes a metal submount 76 (which acts as a metal heat sink and can be implemented as a metal slug), as well as gate and drain leads 56′, 58′. In some embodiments, a metal lead frame may be formed that is then processed to provide the metal submount 76 and/or the gate and drain leads 56′, 58′. RF transistor amplifier 52′ also includes a plastic overmold 62′ that at least partially surrounds the HEMT 11, the leads 56′, 58′ and the metal submount 76. The plastic overmold 62′ replaces the ceramic sidewalls and lid 62 included in RF transistor amplifier 52.

Depending on the aspect, the packaged transistor amplifier 52′ can include, for example, a monolithic microwave integrated circuit (MMIC) as the HEMT 11 in which case the HEMT 11 incorporates multiple discrete devices. When the HEMT 11 is a MMIC implementation, the input matching circuits 64 and/or the output matching circuits 66 may be omitted (since they may instead be implemented within the HEMT 11) and the bond wires 68 and/or 72 may extend directly from the gate and drain leads 56′, 58′ to the gate bond pad 50 and drain metal contact 48. In some aspects, the packaged RF transistor amplifier 52′ can include multiple RF transistor amplifier die that are connected in series to form a multiple stage RF transistor amplifier and/or may include multiple transistor die that are disposed in multiple paths (e.g., in parallel) to form an RF transistor amplifier with multiple RF transistor amplifier die and multiple paths, such as in a Doherty amplifier configuration.

In other cases, Group III nitride-based RF amplifiers may be implemented as monolithic microwave integrated circuit (“MMIC”) devices in which one or more RF amplifier die(s) are implemented together with their associated impedance matching and harmonic termination circuits in a single, integrated circuit die. Examples of such Group III nitride-based RF amplifiers are disclosed, for example, in U.S. Pat. No. 9,947,616, the entire content of which is incorporated herein by reference.

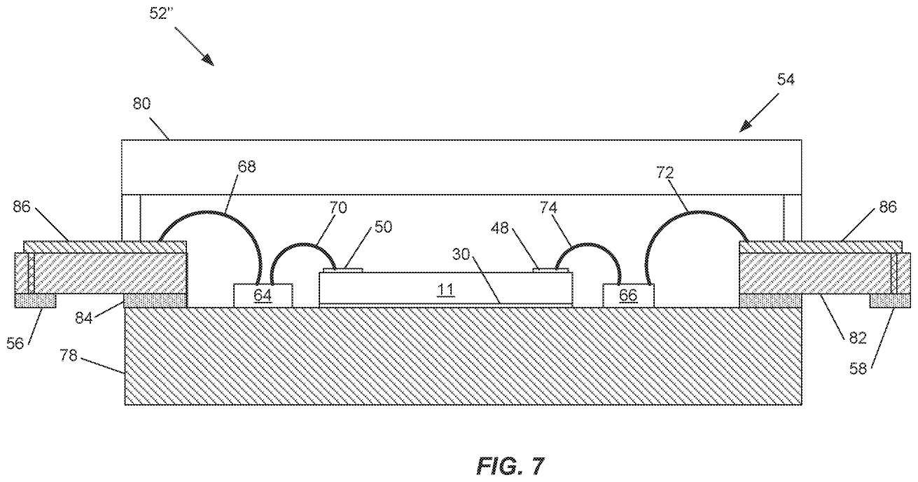

FIG. 7 is a cross-sectional view illustrating an example of a thermally enhanced integrated circuit device package, more specifically a T3PAC package. The T3PAC package 52″ of FIG. 7 can be a ceramic-based package that includes a base 78 and an upper housing with a lid member 80 and sidewall members 82. The lid member 80 and sidewalls 82 similarly define an open cavity surrounding the HEMT 11 on the conductive base or flange 78, which likewise provides both an attachment surface and thermal conductivity (e.g., a heat sink) for dissipating or otherwise transmitting heat outside of the package 52″.

The flange 78 can be an electrically conductive material, for example, a copper layer/laminate or an alloy or metal-matrix composite thereof. In some embodiments, the flange 78 may include a copper-molybdenum (CuMo) layer, CPC (Cu/MoCu/Cu), or other copper alloys, such copper-tungsten CuW, and/or other laminate/multi-layer structures. In the example of FIG. 7, the flange 78 is illustrated as a copper-molybdenum (RCM60)-based structure to which the sidewalls 82 and/or lid member 80 are attached, e.g., by a conductive glue 84.

The flange 78 also provides the source lead for the package 52″. The gate lead 56 and drain lead 58 are provided by respective conductive wiring structure 86 which is attached to the flange 78 and supported by the sidewall members 82.

Aspects of the present invention present numerous advantages over the prior art. In the HEMT 11, by depositing interface layers 42, 44 over the ohmic metal structures of the source and drain terminals 20, 22, such as at the same time the field plate 38 is deposited, and by directly connecting the source terminal 20 to the back side metal layer 30, the thickness of the subsequently deposited metal contacts 46, 48 may be substantially reduced, without loss of performance in operation at high power and/or high frequency. Because the metal contacts 46, 48 are formed from expensive metals, such as gold, this reduction in metal contacts thickness directly reduces the overall cost of the HEMT 11, such as by approximately 15%.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein. Although steps of various processes or methods described herein may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention.

What is claimed is:

1. A semiconductor transistor comprising:
a substrate having upper and lower surfaces;
a semiconductor transistor structure formed on the upper surface of the substrate;
source and drain terminals formed directly on the semiconductor transistor structure, the source and drain terminals comprising an ohmic metal structure having a first conductivity;
an interface layer formed directly on each of the source and drain terminals, the interface layers comprising a field plate metal structure having a second conductivity greater than the first conductivity, the interface layers having a first thickness; and
a metal contact formed directly on each interface layer, the metal contacts comprising a metal construction having a third conductivity greater than the first conductivity, the metal contacts having a second thickness greater than the first thickness.

2. The transistor of claim 1, further comprising:
a via through the substrate and electrically connected to a conductive layer formed on the lower surface of the substrate;
wherein the source terminal is formed over both the via and the semiconductor transistor structure.

3. The transistor of claim 1, further comprising:
a gate terminal formed directly on the semiconductor transistor structure between the source and drain terminals;
a dielectric layer formed over the gate terminal; and
a field plate formed at least partially over the gate terminal and extending at least partially towards the drain terminal, the field plate comprising the field plate metal structure.

4. The transistor of claim 3, wherein the field plate is electrically connected to the source terminal.

5. The transistor of claim 4, wherein the field plate is electrically connected to the source terminal by one or more conductive paths over an active area of the transistor between the source and drain terminals.

6. The transistor of claim 4, wherein the field plate is electrically connected to the source terminal by one or more conductive paths routed outside an active area of the transistor between the source and drain terminals.

7. The transistor of claim 1, wherein each interface layer covers most, but not all, of the respective source and drain terminals.

8. The transistor of claim 1, wherein each metal contact covers most, but not all, of the respective interface layer.

9. The transistor of claim 1, wherein the semiconductor transistor structure is a High Electron Mobility Transistor (HEMT).

10. The transistor of claim 9, wherein the HEMT is a GaN HEMT.

11. A method of manufacturing a semiconductor transistor comprising:
providing a substrate having upper and lower surfaces;
forming a semiconductor transistor structure on the upper surface of the substrate;
forming source and drain terminals directly on the semiconductor transistor structure, the source and drain terminals comprising an ohmic metal structure having a first conductivity;
forming an interface layer directly on each of the source and drain terminals, the interface layers comprising a field plate metal structure having a second conductivity greater than the first conductivity, the interface layers having a first thickness; and
forming a metal contact directly on each interface layer, the metal contacts comprising a metal construction having a third conductivity greater than the first conductivity, the metal contacts having a second thickness greater than the first thickness.

12. The method of claim 11, further comprising:
forming a via through the substrate and electrically connecting the via to a conductive layer formed on the lower surface of the substrate;
wherein forming the source terminal comprises forming the source terminal over both the via and the semiconductor transistor structure.

13. The method of claim 11, further comprising:
forming a gate terminal directly on the semiconductor transistor structure between the source and drain terminals;
forming a dielectric layer over the gate terminal; and
forming a field plate at least partially over the gate terminal, the field plate extending at least partially towards the drain terminal, the field plate comprising the field plate metal structure.

14. The method of claim 13, further comprising electrically connecting the field plate to the source terminal.

15. The method of claim 14, wherein electrically connecting the field plate to the source terminal comprises electrically connecting the field plate to the source terminal by one or more conductive paths over an active area of the transistor between the source and drain terminals.

16. The method of claim 14, wherein electrically connecting the field plate to the source terminal comprises electrically connecting the field plate to the source terminal by one or more conductive paths routed outside an active area of the transistor between the source and drain terminals.

17. The method of claim 11, wherein forming each interface layer comprises covering most, but not all, of the respective source and drain terminals.

18. The method of claim 11, wherein forming each metal contact comprises covering most, but not all, of the respective interface layer.

19. The method of claim 11, wherein forming a semiconductor transistor structure comprises forming a High Electron Mobility Transistor (HEMT).

20. The method of claim 19, wherein the forming a HEMT comprises forming a GaN HEMT.
